(19) United States
(12) Patent Application Publication
(10) Pub. No.: US 2011/0107968 A1
(43) Pub. Date: May 12, 2011

(54) SEMICONDUCTOR MANUFACTURING APPARATUS

(75) Inventors: Taek Yong Jang, Gyeonggi-do (KR); Byung Il Lee, Gyeonggi-do (KR); Young Ho Lee, Gyeonggi-do (KR); Seung Beom Baek, Gyeonggi-do (KR)

(73) Assignee: TERASEMICON CORPORATION, Gyeonggi-do (KR)

(21) Appl. No.: 12/674,578

(22) PCT Filed: Sep. 14, 2007
(86) PCT No.: PCT/KR2007/004457

§ 371 Date: Feb. 22, 2010

(30) Foreign Application Priority Data
Aug. 22, 2007 (KR) 10-2007-0084346
Sep. 14, 2007 (KR) PCT/KR2007/004457

(51) Int. Cl. C23C 16/455; C23C 16/458; C23C 16/46

(52) U.S. Cl. 118/720; 118/725

(57) ABSTRACT

A semiconductor manufacturing apparatus includes: a reaction chamber for providing an airtight process space; a boat for loading/unloading a pair of semiconductor substrates into/from the reaction chamber, wherein the boat includes susceptors and rotary tables to be rotatably supported by a plurality of supporting rollers, each semiconductor substrate being mounted onto each susceptor and each susceptor being mounted onto each rotary table, respectively; heaters, arranged at backsides of the semiconductor substrates, for performing an epitaxial process in the reaction chamber; a process gas nozzle, installed to encircle an upper fringe of the semiconductor substrates; an exhaust gas nozzle, installed to encircle a lower fringe of the semiconductor substrates; and a purge gas nozzle for supplying a purge gas capable of preventing an outer wall of the process gas nozzle from being deposited, wherein the purge gas nozzle is arranged near to the process gas nozzle.

### TECHNICAL FIELD

The present invention relates to a semiconductor manufacturing apparatus; and more particularly, to the semiconductor manufacturing apparatus for forming an epitaxial layer on a pair of semiconductor substrates by processing the semiconductor substrates which stand in a vertical direction and face each other.

### BACKGROUND ART

In general, an epitaxial layer is formed by growing a monocrystalline layer having the same or different material as or from a monocrystalline wafer on a surface of the monocrystalline wafer. A semiconductor device may have good characteristics if formed on the epitaxial layer of good quality.

A chemical vapor deposition (CVD) is widely used as a method for forming a silicon epitaxial layer, in which a silicon monocrystalline is grown by supplying silicon source gas such as SiCl₄, SiHCl₃, SiH₂Cl₂ or SiH₄ etc. along with carrier gas such as hydrogen onto a silicon wafer heated at a high temperature.

In addition, when the epitaxial layer is formed, a single type process in which one wafer is processed at a batch is preferably adopted by considering points that a high temperature environment which causes the deflection of the silicon wafer may be established and that it is important to control the distribution of the process gas in order to achieve the uniformity of a film. However, since such a single type process is underproductive, it is necessary to develop a semiconductor manufacturing system capable of growing the epitaxial layer on two or more wafers at the same time.

### DISCLOSURE

### Technical Problem

However, since a high temperature environment of about 1000° C. is required as a process temperature in order to grow the epitaxial layer, it is difficult in designing a semiconductor manufacturing system even though only two wafers are to be processed at the same time. In specific, it is necessary to develop a semiconductor manufacturing system capable of uniformly controlling all process parameters such as a substrate temperature, a gas pressure, a gas composition and a gas flow and so on for each of the wafers which stand in the vertical direction and face each other, wherein each process parameter may have an effect on characteristics of the epitaxial layer.

### Technical Solution

It is, therefore, a primary object of the present invention to provide a semiconductor manufacturing apparatus for forming an epitaxial layer on a pair of semiconductor substrates which stand in a vertical direction and face each other.

### Advantageous Effects

The semiconductor manufacturing apparatus in accordance with the present invention can improve the productivity significantly in that an epitaxial layer of good quality can be grown on each of the wafers at the same time.

### DESCRIPTION OF DRAWINGS

The above and other objects and features of the present invention will become apparent from the following description of preferred embodiments given in conjunction with the accompanying drawings, in which:

FIG. 1A provides an explanatory view showing an external appearance of a semiconductor manufacturing apparatus in accordance with the present invention;

FIG. 1B depicts a conceptual view illustrating an arrangement of a process gas nozzle and an exhaust gas nozzle of the semiconductor manufacturing apparatus in accordance with the present invention;

FIG. 2A represents a deal drawing illustrating a rotary table in accordance with the present invention;

FIGS. 2B and 2C present enlarged views illustrating rotary tables and a driving part connected to the rotary tables, respectively;

FIG. 3A provides a cross-sectional view showing the semiconductor manufacturing apparatus which includes the rotary tables;

FIG. 3B furnishes an enlarged cross-sectional view illustrating an upper portion of FIG. 3A;

FIG. 4 offers a conceptual view illustrating the semiconductor substrate and a nozzle arranged in a divided heating area;

FIG. 5A represents a diagram illustrating a profile of FIG. 1B;

FIG. 5B depicts an enlarged cross-sectional view of a lifting part of FIG. 5A; and

FIG. 5C shows a cross-sectional view corresponding to FIG. 5A.

### BEST MODE

In accordance with one aspect of the present invention, there is provided a semiconductor manufacturing apparatus including: a reaction chamber for providing an airtight process space; a boat for loading/unloading a pair of semiconductor substrates which are facing each other into/from the reaction chamber, wherein the boat includes a pair of susceptors having a shape of a ring and a pair of rotary tables to be rotatably supported by a plurality of supporting rollers, each of the semiconductor substrates being mounted onto each of the susceptors and each of the susceptors being mounted onto each of the rotary tables, respectively; a pair of heaters, arranged at backsides of the pair of the semiconductor substrates, for performing an epitaxial process in the reaction chamber; a process gas nozzle, installed to encircle an upper fringe of the semiconductor substrates, for supplying a process gas; an exhaust gas nozzle, installed to encircle a lower fringe of the semiconductor substrates, for exhausting the process gas; and a purge gas nozzle for supplying a purge gas capable of preventing an outer wall of the process gas nozzle from being deposited, wherein the purge gas nozzle is arranged near to the process gas nozzle.

### MODE FOR INVENTION

In the following detailed description, reference is made to the accompanying drawings that show, by way of illustration, specific embodiments in which the invention may be practiced. These embodiments are described in sufficient detail to enable those skilled in the art to practice the invention. It is to be understood that the various embodiments of the invention, although different, are not necessarily mutually exclusive. For example, a particular feature, structure, or characteristic described herein in connection with one embodiment may be implemented within other embodiments without departing from the spirit and scope of the invention. In addition, it is to be understood that the location or arrangement of individual elements within each disclosed embodiment may be modified without departing from the spirit and scope of the invention. The following detailed description is, therefore, not to be taken in a limiting sense, and the scope of the present invention is defined only by the appended claims, appropriately interpreted, along with the full range of equivalents to which the claims are entitled. In the drawings, like numerals refer to the same or similar functionality throughout the several views.

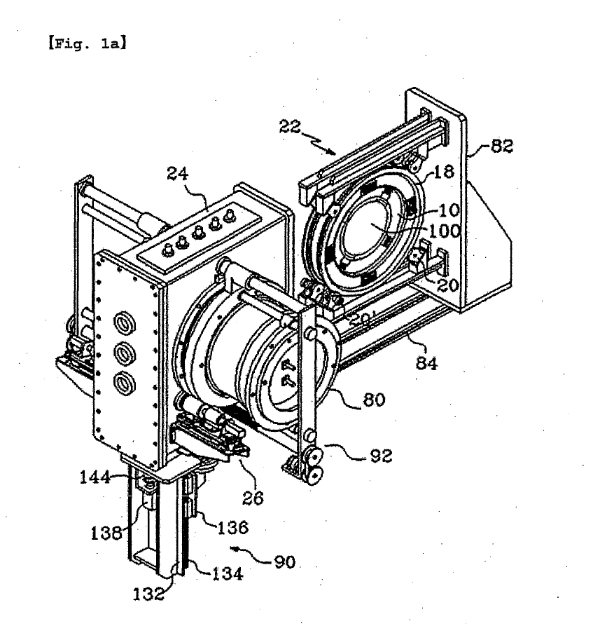

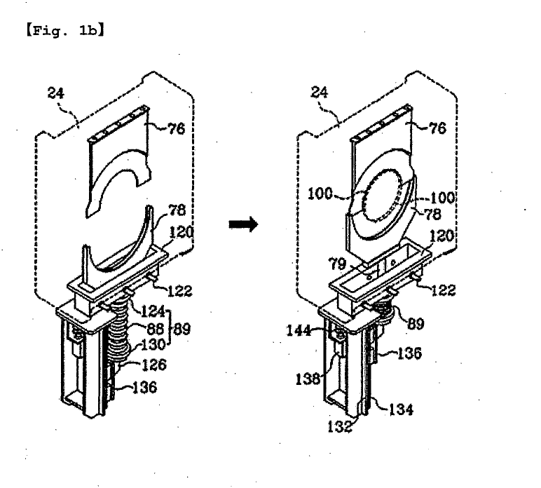

FIG. 1A provides an explanatory view showing an external appearance of a semiconductor manufacturing apparatus in accordance with the present invention; and FIG. 1B depicts a conceptual view illustrating an arrangement of a process gas nozzle and an exhaust gas nozzle of the semiconductor manufacturing apparatus in accordance with the present invention.

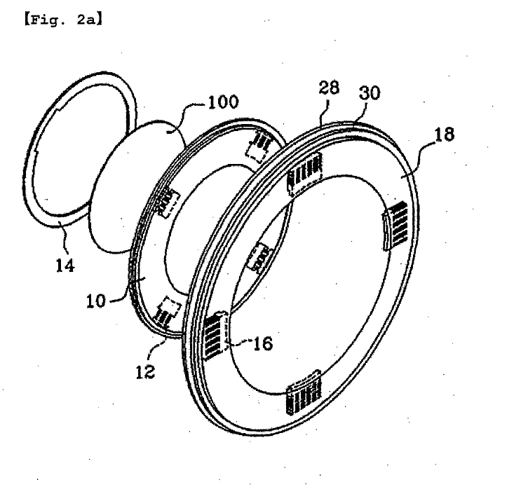

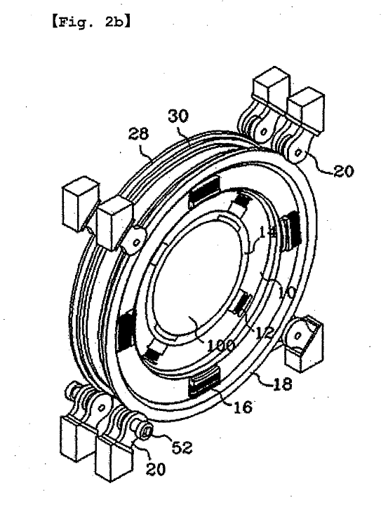

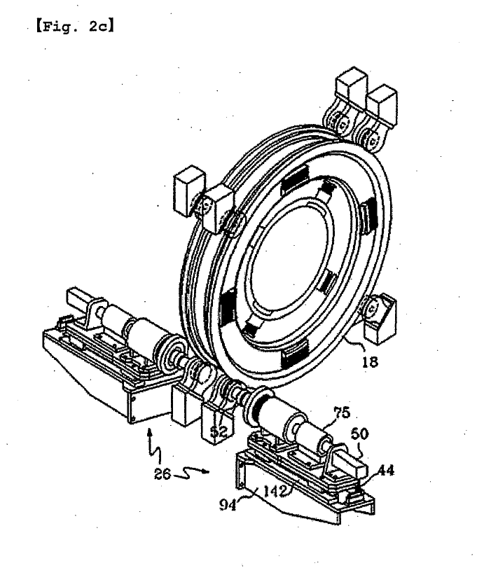

FIG. 2A represents a deal drawing illustrating a rotary table in accordance with the present invention; and FIGS. 2B and 2C present enlarged views of the rotary tables and a driving part connected to the rotary tables, respectively.

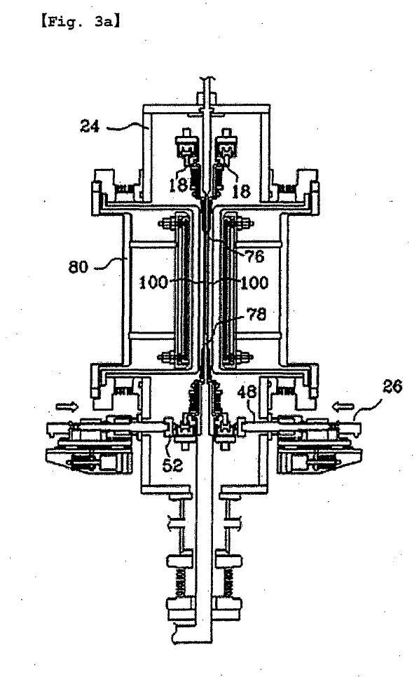

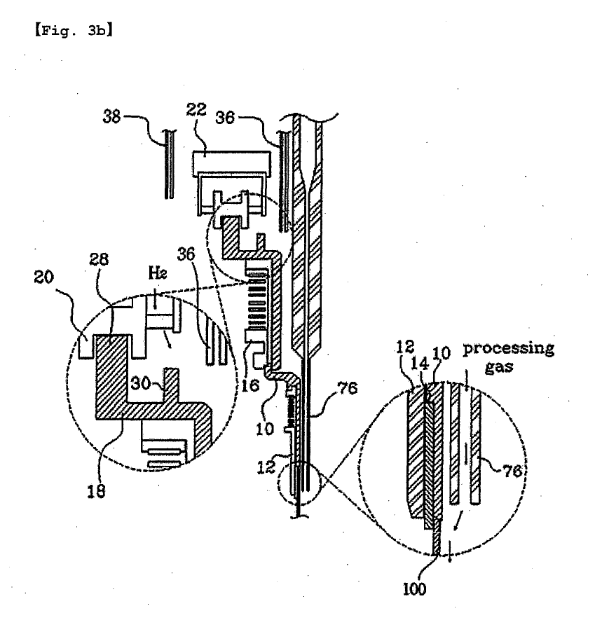

FIG. 3A provides a cross-sectional view of the semiconductor manufacturing apparatus which includes the rotary tables; and FIG. 3B furnishes an enlarged cross-sectional view of an upper portion of FIG. 3A.

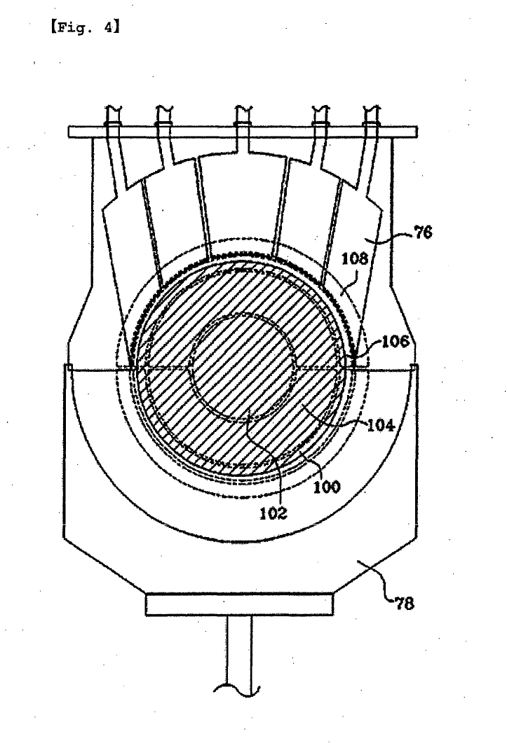

FIG. 4 offers a conceptual view illustrating the semiconductor substrate and the exhaust nozzle arranged in a divided heating area.

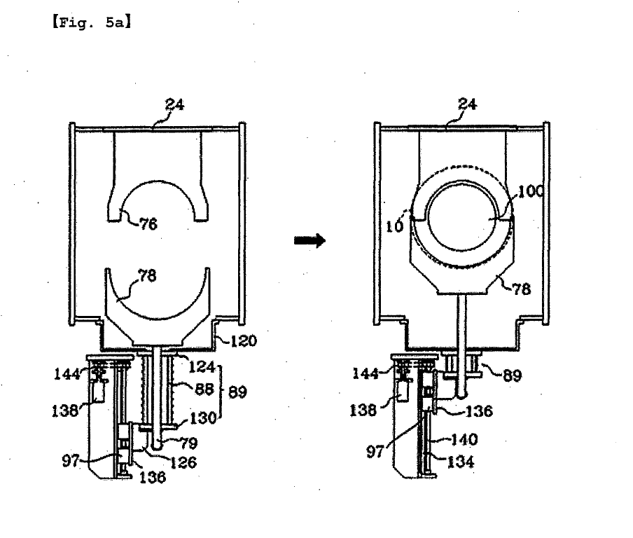

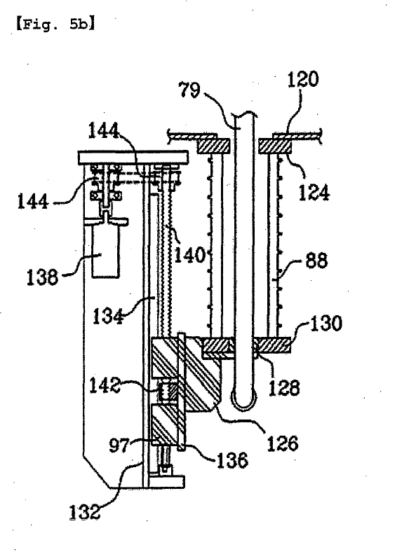

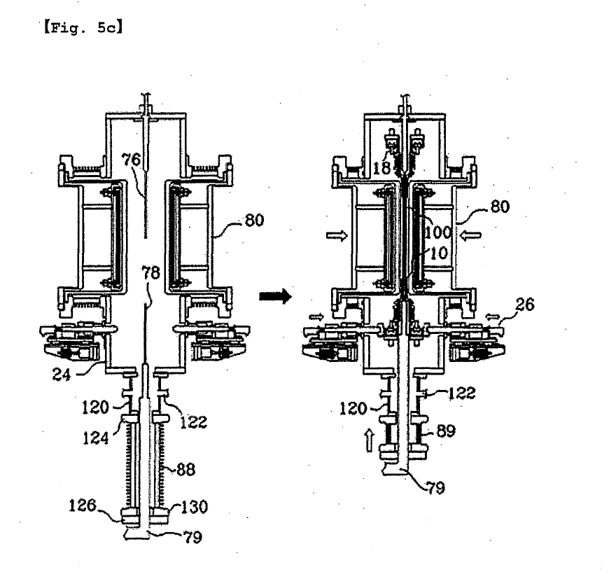

FIG. 5A represents a diagram illustrating a profile of FIG. 1B; and FIG. 5B depicts an enlarged cross-sectional view of a lifting part of FIG. 5A.

FIG. 5C shows a cross-sectional view corresponding to FIG. 5A.

The present invention will now be described in more detail, with reference to the accompanying drawings.

As shown in FIGS. 1A and 1B, the semiconductor manufacturing apparatus in accordance with the present invention includes a reaction chamber 24 for providing an airtight process space. The reaction chamber 24 has room capable of a boat 22 on which a pair of opposed semiconductor substrates 100 and a pair of rotary tables 18 for supporting the semiconductor substrates 100 may be installed.

A process gas nozzle 76 is formed at an upper portion of the reaction chamber 24 so as to encircle an upper fringe of the semiconductor substrates 100 which are processed in the reaction chamber 24 and an exhaust nozzle 78 is formed at a lower portion of the reaction chamber 24 so as to encircle a lower fringe of the semiconductor substrates 100 in order to establish a gas flow from the upper portion toward the lower portion of the reaction chamber 24.

A heater 80 for establishing a high temperature environment in the reaction chamber 24 and a driving part 26 connected to a plurality of supporting rollers 20 of the rotary tables 18 are arranged at both sides of the reaction chamber 24.

In addition, the boat 22 includes a boat cap 82 for providing an airtight space to the reaction chamber 24 by blocking a backside of the rotary tables 18 introduced into the reaction chamber 24, wherein the boat cap 82 is mounted on a moving rail 84.

The semiconductor substrates 100 are mounted on a pair of susceptors 10 of the boat 22 by means of an end effector (not shown) and the susceptors 10 are mounted on the rotary tables 18 by means of the end effector.

The rotary table 18 is divided into the susceptor 10 and a supporting panel 14. The susceptor 10 is attached to the rotary table 18 through rear attaching means 16. Also, the susceptor 10 holds the semiconductor substrate 100 through front attaching means 12 and the supporting panel 14.

Referring to FIGS. 2A to 3B, the rotary table 18 on which the semiconductor substrate 100 is loaded is described as follows:

The susceptor 10 is open to a front side of the semiconductor substrate(s) 100 (i.e., a process reaction side) in such a manner that a circumference of the front side of the semiconductor substrate 100 interferes with the susceptor 10 slightly. Moreover, the supporting panel 14 with a shape of a ring is attached to the susceptor 10 by means of the front attaching means 12 in such a manner that a circumference of a backside of the semiconductor substrate 100 interferes with the supporting panel 14 slightly. Accordingly, the semiconductor substrate 100 is not pressurized by the front attaching means 12.

Next, the rotary table 18 has a shape of a convex dish in order to closely make the loaded semiconductor substrates 100 face each other, wherein a protrusion of a driving circumference portion 28 is formed at the circumference of the rotary table 18 and in contact with the supporting roller 20.

In order to prevent minute dust in the supporting roller 20 from being penetrated into the semiconductor substrates 100, an antifouling ring 30 is preferably protruded on the circumference of the rotary table 18 between the driving circumference portion 28 and the semiconductor substrate 100 so as to surround the semiconductor substrate 100.

That is, the antifouling ring 30 serves as a protrusion structure capable of physically coping with the penetration of the minute dust.

Furthermore, an atmospheric gas nozzle 38 for supplying an atmospheric gas to space between the rotary tables 18 facing each other is formed at the reaction chamber 24 in order to maintain an atmosphere in the reaction chamber 24 and prevent the penetration of the minute dust. Herein, it is desirable to form a gas curtain through the atmospheric gas provided by the atmospheric gas nozzle 38, wherein the kind of the provided atmospheric gas may be H₂.

What is more, a purge gas nozzle 36 for supplying purge gas to space between the rotary tables 18 facing each other is formed at the reaction chamber 24 in order to prevent an unnecessary deposition on an outer wall of the process gas nozzle 76 which may be caused by a back-streaming process gas.

At this time, it is desirable that one end of the purge gas nozzle 36 is installed in such a manner that it is maximally close to one end of the process gas nozzle 76 as depicted in FIG. 3C in order to prevent a deposition of a silicon layer on an outer wall of the process gas nozzle 76. Describing in more detail, one end of the purge gas nozzle is formed in close to an outer circumference of the antifouling ring 30 which is formed at an outer circumference of the rotary tables 18. However, it is desirable to separate one end of the purge gas nozzle 36 from the outer circumference of the antifouling ring 30 in order not to disturb the movement of the purge gas.

Herein, the kind of the provided purge gas from purge gas nozzle 36 may be H₂.

The purge gas injected into the reaction chamber 24 is discharged through a purge exhaust pipe 122 formed at a standby chamber 120.

In the mean time, in case the semiconductor substrates 100 are loaded on the rotary tables 18, the semiconductor substrates 100 stand in a vertical direction and face each other. Also, the rotary tables 18 can be rotated by the supporting rollers 20.

As shown in FIG. 2B, any one of the supporting rollers 20 of the rotary tables 18 includes a connecting means 52 having a spline groove used for connecting to a driving shaft 48 of the driving part 26.

After the boat 22 is loaded into the reaction chamber 24 by means of the connecting means 52, the driving part 26 is transferred, resulting in the contact as shown in FIG. 2C.

Then, the driving part 26 includes a supporting frame 94 formed at the outside of the reaction chamber 24, and a rail 142 and a transferring panel 44 for sliding along the rail 142 are formed at the supporting frame 94.

Moreover, a transferring unit 46 for making the transferring panel 44 go and return is formed at the supporting frame 94, and a driving motor 50 having the driving shaft 48 for rotating the supporting rollers 20 is formed at the transferring panel 44. Also, any one of the supporting rollers 20 of the rotary tables 18 includes the connecting means 52 which comes in contact with the driving shaft 48 as described above.

At this time, the reaction chamber 24 is sealed by the driving part 26 which is in contact therewith. Since the purge gas such as the explosive H₂ is introduced into the reaction chamber 24, it is necessary to prevent the purge gas from being flowing out of the reaction chamber 24. Also, in order to provide a low pressure (a vacuum) environment for carrying out the process and prevent the outflow of a waste gas (a poison gas) during the process, it is necessary to seal the reaction chamber 24.

Each element of the heaters 80 including a heater loading part 92 will now be described in more detail with reference to FIG. 1A, FIG. 1B and FIG. 4. As shown in the drawings, the driving part 26 is omitted in order not to superimpose the driving part 26 on the heater loading part 92.

For explanatory convenience, since each of the heaters have a symmetrical structure, only one half of the heaters 80 is shown in the drawings for convenience' sake.

First, the rotary tables 18 are rotatably mounted on the boat 22 while the circumferences of the rotary tables 18 are in contact with the supporting rollers 20. Also, each of the rotary tables 18 has a shape of the convex dish which is convex in a direction toward the semiconductor substrate 100 in order to closely face the loaded semiconductor substrates 100 each other inside the contact lines of the supporting rollers 20 and the rotary tables 18.

When the semiconductor substrates 100 are loaded on the rotary tables 18, the semiconductor substrates 100 may stand in the vertical direction and face each other, and further, the rotary tables 18 may be rotated by the operation of the supporting rollers 20 as mentioned above.

In the meantime, the heater 80 stands by at the outside of the rotary tables 18, and after the loading of the semiconductor substrates 100 is completed, the heater 80 is inserted into a concave groove of the rotary tables 18 by means of the heater loading part 92 to thereby approach the backside of the semiconductor substrates 100.

In order to allow the moving of the heater 80 through the heater loading part 92 and ensure the airtightness of the reaction chamber 24, the heater 80 can be separated from the reaction chamber 24.

After the heater 80 is mounted on the reaction chamber 24, the rotary tables 18 are rotated to perform the process. During the process, the reaction gas may be injected and discharged from the space between the opposed semiconductor substrates 100, and a high temperature environment may be established by means of the heater 80.

At this time, in order to grow a film on a reaction surface of the semiconductor substrates 100, it is necessary to provide an appropriate high temperature environment on the semiconductor substrates 100. To this end, the heater 80 has a heating surface which encircles the whole area of the semiconductor substrates 100 in order to heat the opposed semiconductor substrates 100 from the backside of the semiconductor substrates 100.

The exhaust nozzle 78 including a lifting part 90 will be described with reference to FIGS. 1A to 10 and FIGS. 5A to 5C.

The rotary tables 18 are rotatably installed at the boat 22 while the circumferences of the rotary tables 18 are in contact with the supporting rollers 20 as described above. Further, the rotary tables 18 are in the shape of the convex dish in the faced direction so as to come close to the loaded semiconductor substrates 100 inside the contact lines of the supporting rollers 20.

The process gas nozzle 76 is located at the upper portion of the reaction chamber 24 and the exhaust nozzle 78 is located at the lower portion of the reaction chamber 24 in order to establish a gas flow from the upper portion of the reaction chamber 24 toward the lower portion of the reaction chamber 24.

At this time, since the process gas nozzle 76 is thin enough to evade the interference with the susceptors 10 during the loading/unloading of the boat 22, the process gas nozzle 76 may be fixed to the reaction chamber 24.

In the meantime, the process gas nozzle 76 may make the process gas provided toward the semiconductor substrates 100 diffuse with ease and the flow of the process gas on the semiconductor substrates 100 be uniform.

In the meantime, the exhaust nozzle 78 is separated from the reaction chamber 24 and is separately provided with the boat 22. Accordingly, the exhaust nozzle 78 stands by at the lower portion of the boat 22 in order to escape the interference with the boat 22 prior to the loading/unloading of the boat 22 into/from the reaction chamber 24.

The exhaust nozzle 78 requires an inlet having a large suction opening in order to collect the reaction gas unlike the process gas nozzle 76. That is, the exhaust nozzle 78 is maximally close between the opposed susceptors 10 in order to collect the injected reaction gas.

Herein, since the moving range of the boat 22 is large, it is undesirable in terms of the systematic reliability if the boat 22 is provided along with the exhaust nozzle 78 and its peripheral device.

At this time, in case the exhaust nozzle 78 is fixed to the reaction chamber 24, it can be rubbed with the susceptors 10 (between the susceptors 10) on the moving path of the boat 22, and thus, the minute dust is generated in the reaction chamber 24, thereby contaminating the process space.

Accordingly, the lifting part 90 is formed at the exhaust nozzle 78 to make the exhaust nozzle 78 stand by at the lower portion of the opposed susceptors 10 prior to the loading/unloading of the boat 22 into/from the reaction chamber 24 and be loaded between the susceptors 10 after the loading of the boat 22 is completed.

In the concrete, the exhaust nozzle 78 is arranged in a form of a semicircle between the susceptors 10 so as to surround the lower portion of the opposed semiconductor substrates 100. Moreover, the exhaust nozzle 78 is installed at the reaction chamber 24 in such a manner that both ends of the exhaust nozzle 78 are separated from the susceptors 10 when the exhaust nozzle 78 is standing by.

In addition, the standby chamber 120 in which the exhaust nozzle 78 may stand by is formed at the lower portion of the reaction chamber 24.

In case the considerable portion of the exhaust nozzle 78 is located in the standby chamber 120, the purge gas is collected by the standby chamber 120 which is separately provided and fixed to the reaction chamber 24 during the process.

In the meantime, the lifting part 90 is located at the lower portion of the reaction chamber 24, wherein the exhaust nozzle 78 and a bellows cover 89 are combined with the lifting part 90.

To be specific, the bellows cover 89, which is a part of the reaction chamber 24 and provided to arrange an exhaust pipe 79 of the exhaust nozzle 78, is connected to both a reaction chamber mounting ring 124 mounted by surrounding an outer circumference of a through hole of the standby chamber 120 and a bracket mounting ring 130 mounted on a coupling bracket 126 for lifting the exhaust nozzle 78.

Further, the bellows cover 89 seals the space between the reaction chamber mounting ring 124 and the bracket mounting ring 130, and at the same time, the bellows cover 89 allows the movement through the lifting part 90.

Next, the lifting part 90 includes a supporting frame 132 formed at the outside of the reaction chamber 24, and the rail 134 and a lifting panel 136 for sliding along the rail 134 formed at the supporting frame 132.

Moreover, the coupling bracket 126 is mounted on the lifting panel 136 to thereby be coupled to the exhaust pipe 79 and the bracket mounting ring 130.

In the meantime, a lifting motor 138 is formed at the supporting frame 132 and a transferring bolt 140 is formed near the supporting frame 132, wherein the transferring bolt 140 receives the driving force from the lifting motor 138 by means of a pulley 144.

A transferring nut 97 may convert the rotational move into the lineal move (going up and down) by interlocking with the transferring bolt 140, wherein the transferring nut 97 may be moved while combined with the lifting panel 136.

Accordingly, the exhaust nozzle 78 goes down to maintain the standby status prior to loading of the semiconductor substrates 100 into the reaction chamber 24 or prior to unloading of the semiconductor substrates 100 from the reaction chamber 24 at the time of the completion of the process.

At this time, the bellows cover 89 surrounds the outer circumference of the exhaust pipe 79 while maintaining its tensile status.

Subsequently, after loading the semiconductor substrates 100 into the reaction chamber 24, by driving the lifting motor 138, the transferring bolt 140 is rotated by the pulley 144 and the transferring nut 97 combined with the transferring bolt 140 is lifted, and thus the lifting panel 136 is lifted along the rail 134.

Further, since both the coupling bracket 126 and the bracket mounting ring 130 coupled to the lifting panel 136 are lifted, the exhaust nozzle 78 is also lifted, and thus a suction portion of the exhaust nozzle 78 is inserted between the susceptors 10 so as to encircle the lower portion of the circumference of the semiconductor substrates 100.

At this time, the bellows cover 89 attached to the coupling bracket 126 is compressed to maintain the airtightness between the exhaust pipe 79 and the reaction chamber 24.

Then, the driving part 26 moves toward the rotary tables 18 to contact therewith and the heater 80 is inserted into the inner space of the rotary tables 18 through the heater loading part 92 in order to treat the process of the semiconductor substrates 100. After the process treatment is completed, the exhaust nozzle 78 is descended in order to withdraw the boat 22, which is progressed in reverse order of the above-mentioned process.

A semiconductor manufacturing process in accordance with the present invention will be described in detail as follows:

The opposed semiconductor substrates 100 are loaded into the reaction chamber 24 which provides the airtight process space.

Thereafter, the transferring unit 46 is driven to treat the semiconductor substrates 100, and one of the supporting rollers 20 of the rotary tables 18 comes in contact with the driving shaft 48 for the drive.

In the meantime, a heating surface of the heaters 80 may be arranged maximally close to the backside of the semiconductor substrates 100 by moving the heaters 80 toward the backside of the semiconductor substrates 100 through the heater loading part 92.

In addition, the exhaust nozzle 78 which encircles the lower half portion of the semiconductor substrate 100 is inserted into the space between the opposed susceptors 10 by the lifting part 90.

Herein, the driving shaft 48 in contact with the driving roller 20, the heaters 80 moved toward the backside of the semiconductor substrates 100, and the exhaust nozzle inserted into the space between the susceptors 10 maintain the airtightness with the reaction chamber 24 by means of the bellows cover 89 while they are moving.

After the heaters 80 are arranged at the backside of the semiconductor substrates 100 by the heater loading part 92, the driving part 26 is driven to rotate the rotary tables 18, and thus elevate the temperature of the heating surface of the heaters 80.

At this time, the atmospheric gas nozzle 38 supplies the atmospheric gas (H₂ gas) toward the respective backsides of the semiconductor substrates 100, thereby maintaining the atmosphere in the reaction chamber 24. Moreover, the atmospheric gas nozzle 38 forms the gas curtain between the susceptors 10 and the supporting rollers 20 located at the outer circumference of the rotary tables 18, thereby preventing the minute dust from being penetrated into the inner space of the rotary tables 18. Furthermore, the purge gas nozzle 36 supplies the purge gas (H₂ gas) toward the outer circumference of the rotary tables 18, thereby preventing a silicon layer from being formed at the outer wall of the process gas nozzle 76 by the back-streaming process gas. At this time, it is desirable that one end of the purge gas nozzle 36 is installed in close to the process gas nozzle 76 so as to increase efficiency of preventing a deposition of a silicon layer on an outer wall of the process gas nozzle 76.

The heaters 80 may heat the semiconductor substrates 100 as mentioned above, and further, the heating regions on the semiconductor substrates 100 heated by the heaters 80 having shapes of the concentric circles may be divided into a central portion, a circumference portion and a buffer portion thereof. Accordingly, each of the heating regions may have a different temperature distribution. Further, the heat treatment is performed for the upper and the lower portions of the semiconductor substrates 100 by dividing the heating regions into at least two partitions, i.e., the upper and the lower partitions.

At this time, the process gas may be preheated and then injected on the condition that the outlet of the process gas nozzle 76 is disposed near the buffer portion of the semiconductor substrates 100.

While the invention has been shown and described with respect to the preferred embodiments, it will be understood by those skilled in the art that various changes and modifications may be made without departing from the spirit and the scope of the invention as defined in the following claims.

What is claimed is:

1. A semiconductor manufacturing apparatus comprising:
a reaction chamber for providing an airtight process space;
a boat for loading/unloading a pair of semiconductor substrates which are facing each other into/from the reaction chamber, wherein the boat includes a pair of susceptors having a shape of a ring and a pair of rotary tables to be rotatably supported by a plurality of supporting rollers, each of the semiconductor substrates being mounted onto each of the susceptors and each of the susceptors being mounted onto each of the rotary tables, respectively;
a pair of heaters, arranged at backsides of the pair of the semiconductor substrates, for performing an epitaxial process in the reaction chamber;
a process gas nozzle, installed to encircle an upper fringe of the semiconductor substrates, for supplying a process gas;
an exhaust gas nozzle, installed to encircle a lower fringe of the semiconductor substrates, for exhausting the process gas; and
a purge gas nozzle for supplying a purge gas capable of preventing an outer wall of the process gas nozzle from being deposited, wherein the purge gas nozzle is arranged near to the process gas nozzle.

2. The apparatus of claim 1, further comprising: a driving part for rotating the pair of the rotary tables by contacting any one of the plurality of the supporting rollers after the boat is loaded into the reaction chamber.

3. The apparatus of claim 1, further comprising: a heater loading part for moving the pair of the heaters near to the backsides of the semiconductor substrates by inserting the heaters into an inner space of the susceptors after the boat is loaded into the reaction chamber.

4. The apparatus of claim 1, further comprising: a nozzle lifting part for locating the exhaust gas nozzle at a lower portion of the reaction chamber to avoid an interference between the exhaust gas nozzle and the pair of the susceptors before the boat is loaded into the reaction chamber, and for inserting the exhaust gas nozzle into the pair of the susceptors to encircle the lower fringe of the semiconductor substrates after the boat is loaded into the reaction chamber.

5. The apparatus of claim 1, further comprising: an atmospheric gas nozzle for supplying an atmospheric gas capable of maintaining an atmosphere in the reaction chamber and preventing the backsides of the semiconductor substrates from being deposited.
